(19) United States
(12) Patent Application Publication
(10) Pub. No.: US 2024/0145989 A1
(43) Pub. Date: May 2, 2024

(54) SUPPLEMENTAL SPRING LOCK FOR CONNECTOR INTERFACE

(71) Applicant: VALEO NORTH AMERICA, INC., Troy, MI (US)

(72) Inventors: Samuel Alejandro BERTADILLO, Queretaro (MX); Jazmin Amalinalli AGUILAR, Queretaro (MX)

(73) Assignee: VALEO NORTH AMERICA, INC., Troy, MI (US)

(21) Appl. No.: 18/051,314

(22) Filed: Oct. 31, 2022

(51) Int. Cl. H01R 13/627; H01R 12/70; H01R 13/6581

(52) U.S. Cl. CPC H01R 13/6272; H01R 12/70; H01R 13/6581; H01R 2201/26

(57) ABSTRACT

The present invention pertains to a spring-induced locking feature applied to an electrical connector that includes the associated connector's body and a flexible element that interfaces against the connector's body to supplement a means of secured retention. The connector is configured to be coupled with a wiring harness and connector receptacle to ensure a maintained electrical contact in during operation with vibrational exposure. The supplemental locking feature is configured to secure the electrical connector in-place to an assembly and maintain electrical interfaces by preventing detachment of the electrical connector.

### TECHNICAL FIELD

The present invention relates to securing electrical connector interface arrangements, and more particularly to electrical interface locking features of automotive hardware connectors.

### BACKGROUND OF THE INVENTION

A connector is a device used to join electrical terminals that complete an electric circuit. The connector can include a receptacle component that receives a plug to form a physical connection between the receptacle and the plug. The receptacle has metal contacts (or other electrically conductive material) that contact with interfacing metal contacts (or other electrically conductive material) of the plug to establish a metal-to-metal contact that completes an electrical connection when the receptacle is joined with the plug. Typically, the receptacle is removably connected to the plug. Removable connectors allow assembly and disassembly of interface connections in order connect-disconnect from an electrical circuit or facilitates replacement of faulty components within the electrical system.

Electrical connectors are typically used in automotive lighting. A vehicle's main wiring harness can include a connector that interfaces to a vehicle lighting system such as a headlight or taillight. By example, a connector of the main harness can be a receptacle that mates with a plug on the edge of an electronic circuit board containing at least one light source [e.g. light emitting diode (LED)] of the vehicle lighting system. Typical connectors can but don't always include a primary locking mechanism to ensure electrical continuity and preventions of connector separations that would result in system failures.

Automotive connectors typically include locking mechanism features on the connector itself to ensure that electrical connections are established and maintained. Applications of the typical primary locking mechanism would serve as a source to reliably maintain secure electrical connections if a retention lock is used at all. But such locking mechanisms can be prone to fault and defects under harsh environmental conditions or when induced by vibrations or shock that can dislodge connectors over time or sufficiently loosen a primary locking feature at the interface and break electrical continuity, which results in failures with an associated module or lighting device.

Placement of locking mechanisms on the connector itself increases the complexity and cost of an electrical connector but may still not reliably secure connections and sometimes still not prevent problems that contribute to failed lighting modules. During lighting system assembly, blind operations of joining connectors can contribute to failures because assemblers cannot directly view or accurately ascertain established connections. Moreover, safety gloves and hearing protection apposed in production environments can make it difficult for workers to perceive audible or tactile feedback that can confirm proper engagements or interfacing of connectors. Such circumstances may contribute to defective connectors that do not properly engage or become broken during assembly.

Connectors may also become only partially joined during assembly without qualifying the full engagement needed for electrical connectivity, which results in failed functional performance of lighting modules. Alternatively, partial engagement or damage to associated locking mechanisms may just merely provide temporary sufficient electrical contact to pass quality control but will ultimately fail when vibration or other vehicle operating conditions are introduced that cause subsequent disconnections and lighting system failures.

Even where electrical connectors are properly connected, failures can occur due to exposure from randomized operating conditions. And complex functionality of modern vehicle lighting modules can cause related lighting module vehicle failures when movement from a dynamic leveling feature of a vehicle headlight causes stresses at mated connector locations with an edge plug of an LED board within the lighting system.

Because such connector problems are often the reported cause of lighting module failures during vehicle operations, this associated problem has also contributed to costly vehicle manufacturer warranty claims. Moreover, quality control tests have revealed lighting device failures traced and attributed to connector interface problems despite primarily applied connector locking mechanisms. As such, there is a need to remedy, reinforce or supplement weak and defective locking mechanisms of connector interfaces in an innovative way by a uniquely devised solution.

### BRIEF SUMMARY OF THE INVENTION

Accordingly, an objective of the present disclosure is to provide a supplemental or secondary locking feature on a connector and to eliminate or reduce connector related interface failures. However, another objective of the present disclosure is to provide an alternative locking mechanism apart from the existing applied in the art, and as such, nothing in this disclosure should be construed to limiting the supplemental lock from serving the purpose of a primary locking feature on a connector should that be desired.

Another objective is to provide an easily removable and inexpensive locking feature that makes it unnecessary to provide a connector locking mechanism on the connector itself. These and other object of the disclosure may be achieved by one or more of the following aspects:

A connector locking device for an electrical or lighting assembly of an automobile comprising: a component shield having a biasing extension along an outer surface of the component shield, the component shield configured to interface along an electrical circuit board; the component shield having a resilient body with a flexible leg along the biasing extension; the resilient body having a number of retention features along a number of edges of the resilient body;

The connector locking device of an embodiment, wherein an engagement detent formed along or within a connector body, the flexible extension configured to engage the connector body such that engagement with the connector body provides an associated connector in a connected state in which the first and second electrical contacts are electrically connected to each other; the biasing extension configured to secure the connector to maintain continuous electrical engagement and conductivity with adjoining electrical interfaces an assembly which includes the connector; and an attachment configured to attach the connector to the site connector during an interface in the connected state.

The connector locking device of an embodiment, wherein the component shield is configured to function as a conductive or thermal heatsink.

The connector locking device of an embodiment, wherein said assembly is incorporated into an automobile product.

The connector locking device of an embodiment wherein the flexible leg is replaced by a flexible extension that extends from a light-blocking structure or polymeric framework.

The connector locking device of an embodiment, wherein the component shield or flexible leg are formed from a metallic or alloy material.

The connector locking device of an embodiment, wherein the connector body or flexible leg are formed from a polymeric material.

The connector locking device of an embodiment, where the component shield is applied to a printed circuit board (PCB) with a light source and a reflector unit for reflecting light generated from the light source within the lighting system.

The connector locking device of an embodiment, wherein the component shield interfaces with the connector through the flexible leg and with the connector body on the PCB through a number of retention pads, which are all contained within an automotive lighting system.

The connector locking device of an embodiment, wherein the component shield interfaces with the connector through the flexible leg and with the connector body that is installed at an engagement location, the component shield at the engagement location secured along the PCB through a number of retention pads, which are all contained within an automotive lighting system;
an engagement detent formed along or within the connector body, the flexible leg configured to engage the connector body to prevent extrication or ejection of the connector or prevent the connector from being disengaged or dislodged from a connector port such that a number of electrical contacts of the connector do not break or separate with the connector port while the flexible leg is engaged with the engagement detent.

An alternate embodiment of a connector locking device for an electrical or lighting assembly of an automobile comprising: an electrical connector installed within a circuit board with a connector body having a number of electrical contacts; an engagement detent formed along or within the connector body; a flexible extension with spring properties extending from a masking structure, the masking structure being a rigid structure; the flexible extension configured to couple with the connector body and configured to place the connector in a locked engagement with a number of adjoining electrical interfaces to maintain continuous electrical engagement or continuity with the adjoining electrical interfaces; the flexible extension also configured to prevent the extrication or ejection of the connector body from a connector port at an engagement location from the circuit board during operation.

The connector locking device of an alternate embodiment, wherein the masking structure is formed from a polymeric material.

The connector locking device of an alternate embodiment, wherein the masking structure possesses light blocking properties.

The connector locking device of an alternate embodiment, wherein the component shield is located at a site location along the pcb; said component shield configured to protect an electrical element encompassed by a shield body.

A method of using a connector locking device for an electrical or lighting assembly system of an automobile comprising, presenting a component shield for installation onto a circuit board or a lighting assembly; installing the component shield by a securing means onto the circuit board or the lighting assembly; flexing a leg from the component shield and directing the leg to engage along a connector body to secure the connector body onto the circuit board or the lighting assembly and prevent extrication or ejection of the connector body from an engagement location during operation of said lighting system.

An alternate embodiment of a connector locking device for an electrical or lighting assembly of an automobile comprising; a flexible leg extended from a light-blocking structure or polymeric framework; the flexible leg configured to exhibit biasing or spring-like characteristics between flexed and un-flexed states; the flexible leg configured to interface at a connector along an electrical printed circuit board (PCB); the flexible leg having a number of retention features at the connector interface locations with said circuit board; an engagement detent formed along or within a connector body; the flexible leg configured to engage the connector body to prevent extrication or ejection of the connector body or prevent the connector from being disengaged or dislodged from a PCB port such that a number of electrical contacts of the connector do not break or separate from the PCB port such that the electrical contacts are configured to maintain continuous electrical engagement and conductivity when the connector is in a connected state.

A method of applying a reinforcement lock for an automobile lighting module system comprising: presenting a printed circuit board (PCB) or an assembly component; installing the securing component or secondary lock at an interface of the PCB or the assembly component; engaging a flexible leg at a body of a receptacle or plug connector at a detent; and providing a retention force against the receptacle or plug connector, which is configured to prevent disassembly or movement of the receptacle or plug connector and prevent breaking electrical continuity within the associated module or assembly.

The method of an alternate embodiment, wherein the flexible leg is replaced by a flexible extension that extends from a light-blocking structure or polymeric framework.

It should be appreciated that the above referenced embodiments and examples are non-limiting, as other embodiment variations can exist within the present invention, as shown and described herein.

### DESCRIPTION OF DRAWINGS

The accompanying drawings, which incorporate and constitute a part of the specification, illustrate one or more embodiments and, together with the description, explain these embodiments. The accompanying drawings have not necessarily been drawn to scale. Any values dimensions illustrated in the accompanying graphs and figures are for illustration purposes only and may or may not represent actual or preferred values or dimensions. Where applicable, some or all features may not be illustrated to assist in the description of underlying features. In the drawings:

FIG. 1 is an exemplary embodiment of a component shield lock device in demonstrative application on an exemplary PCB lighting assembly, according to the present disclosure.

FIG. 2A is an isometric view of the shield locking device illustrated from FIG. 1 according to an embodiment of the present disclosure.

FIG. 2B is an isometric opposing view of the component shield locking device of FIG. 2A.

FIG. 3A is an isometric view of the component shield locking device in the flexed and retention conditions for a typical lighting module system by illustrative example per an exemplary embodiment.

FIG. 3B is an opposing view of the component shield locking device of FIG. 3A in the flexed and retention conditions for a typical lighting module system per an exemplary embodiment of the present disclosure.

FIG. 3C is a detail view of the component shield locking device of FIG. 3A in the flexed and retention conditions per an exemplary embodiment of the present disclosure.

FIG. 4A is an isometric view of a connector locking device according to a flexible-extension embodiment of the present disclosure.

FIG. 4B is an opposing view of the connector locking device of FIG. 4A in the retention condition per the flexible-extension embodiment of the present disclosure.

### DETAILED DESCRIPTION OF THE INVENTION

The description set forth below in connection with the incorporated drawings are intended as a description of various embodiments of the disclosed subject matter and are not necessarily intended to represent any one select embodiment. In certain instances, the description can include specific details for purposes of providing an understanding of the disclosed embodiments. However, it will be apparent to those skilled in the art that the disclosed embodiments can be practiced without those specific details. In some instances, well-known structures and components can be shown in block diagram form in order to avoid obscuring concepts or design variations of the disclosed subject matter.

It is to be understood that terms such as “front,” “rear,” and the like that may be used herein merely describe points of reference and do not necessarily limit embodiments of the present disclosure to any particular orientation or configuration. Furthermore, terms such as “first,” “second,” “third,” etc., merely identify one of a number of portions, components, and/or points of reference as disclosed herein, and likewise do not necessarily limit embodiments of the present disclosure to any particular configuration or orientation.

Furthermore, the terms “about,” “approximately,” “proximate,” “minor” and similar terms generally refer to ranges that include the identified value within a margin of 20 percent, 10 percent or preferably 5 percent in certain embodiments or any values therebetween.

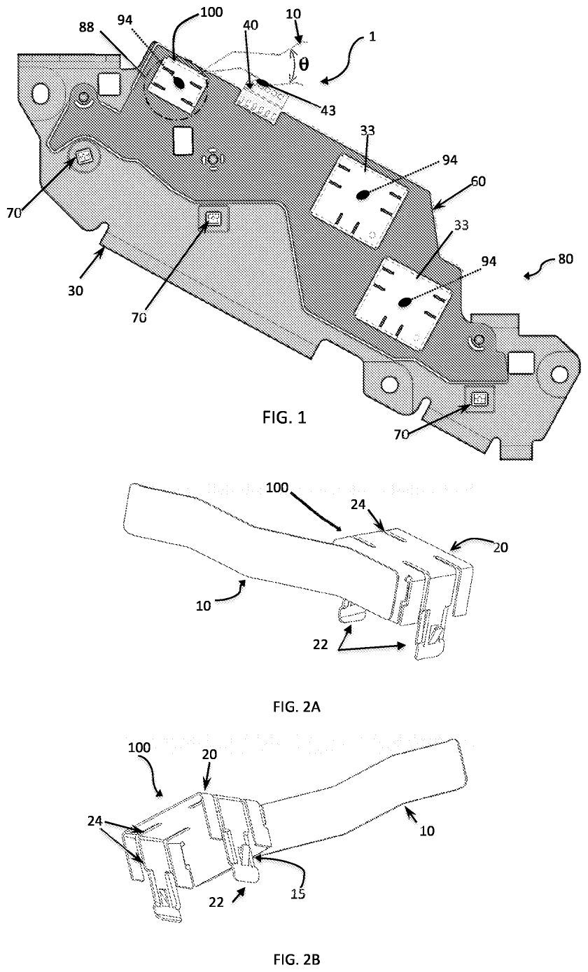

For some perspective, FIG. 1 demonstrably depicts the lighting system 80 with simulated electrical elements 94. Among the distinguished options that can represent electrical components outside of a driver-processor or other common element along the associated PCB 60, another essential component included in the system 80 would involve mounted light sources. A light source 70 represents a luminous source of electromagnetic radiation or an energized source of visually perceived radiant energy (inclusive of “Visible” light of the electromagnetic spectrum) but may include a broad range or combination of electromagnetic or radiant energy inclusive from X-rays, ultraviolet and infrared energy, micro-wave and radio wave spectrums. The light source may include every conventional and suitable lighting element sources such as filament-based or incandescent lamps, fluorescent lamps, arc or gas-discharge type lights, light emitting diodes (LED), or other suitable conventional sources.

FIG. 1 illustratively demonstrates application of the inventive concept in a typical low-beam (LB)—high beam (HB) lighting system 80 where a component shield 100 is installed to protect an electrical element 94 and can function as a heatsink, which extends a flexible leg 10 towards a connector 40 or engagement detent 43 to provide a locking feature that prevents connector dislodging or disconnection from an plug-receptacle interface to a printed circuit board (PCB) 60 or wire harness 46 according to described embodiments.

Component shield 100 can function as a protective shield for an electrical component or driver-processer 94 along a PCB or within an associated assembly. Electrical element 94 represents an essential electrical component or driver-processor unit that is being protected or shielded from damage or isolated against foreign object exposure by the component shield. Electrical element 94 represents a functional electrical component for the operation or control of the associated lighting system 80. Although FIG. 1 illustrates other elements that can serve as a protective shield 33 for similar electrical components 94 along a PCB or an associated assembly, this inventive concept focuses on component shield 100 that presents innovative locking features in the form of flexible retention elements from a sample site location 88.

An engagement detent 43 represents a capture feature formed along or within the connector 40 that contributes to the locking mechanism and functions to interface with a flexible leg 10 of the respective component shield 100. The component shield 100 can typically be emplaced along interfaces 88 of a PCB 60 or system assembly 80 and secured in place by retention pads 22. Site location or interface location 88 represents a mounting or interface placement of the inventive device along PCB attachment points or in contact with similarly associated assemblies.

Site installation can occur directly or through intermediate components to facilitate contact interface. Installation or securing contact can occur either through hardware fastening, weldment, bonding or any suitable conventional means or attachment method. Connector locking feature 1 is intended to supplement any existing primary locking mechanism in association with connector 40, but nothing should be construed to prevent an interpretation that connector locking feature 1 can be used independently applied outside any locking features from the connectors if necessary or desirable, accordingly.

Several disclosed embodiments (FIGS. 1-3C) of a supplemental or secondary locking device 1 are directed to minimize connector related failures. Supplemental or secondary locking device 1 can function to reinforce retention, immovably secure or supplement connections with connector interfaces. The locking feature implements retention through flexible leg 10 against interfacing connector 40 at detent locations 43 to secure components with one another against removability or dislocation between interfaces or to become dislodged from the associated assembly or system.

Flexible leg 10 represents a resilient member that possesses spring-like or biasing characteristics induced within the associated material body when articulated between free-state an flexed conditions. The flexible leg 10 may be formed from a single or multiple segments that form flexible leg 10. The flexible leg 10 functions to induce a force against an interfacing component for retention or fixating purposes. The flexible leg 10 can represent any suitable form or shape necessary to perform the retention or fixation function. An engagement detent 43 represents a capture feature formed along or within the connector 40 that contributes to the locking mechanism and functions to interface with a flexible leg 10 of the respective component shield 100.

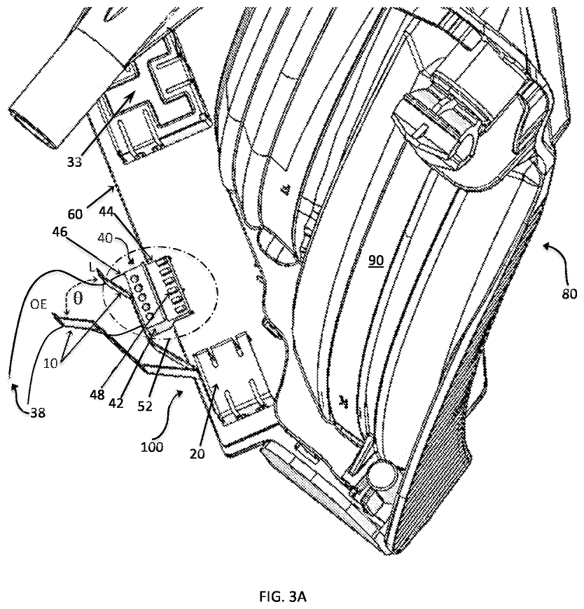

FIGS. 2A and 2B illustrate feature details of component shield 100. Component shield 100 can be formed from a resilient heat conductive material, preferably metallic, which may be manufactured from stamping methods or any suitable conventional method inclusive of weldments, polymeric injections or composite forms. Shield 100 includes portions of cover body 20, flexible leg 10, relief areas 24 and retention pads 22. Feature relief 24 facilitates body formation, heat transfer and aids in weight reduction of the component shield 100. Relief 24 can represent a cutout or material removal feature that functions to promote manufacturing formation of the component shield structure.

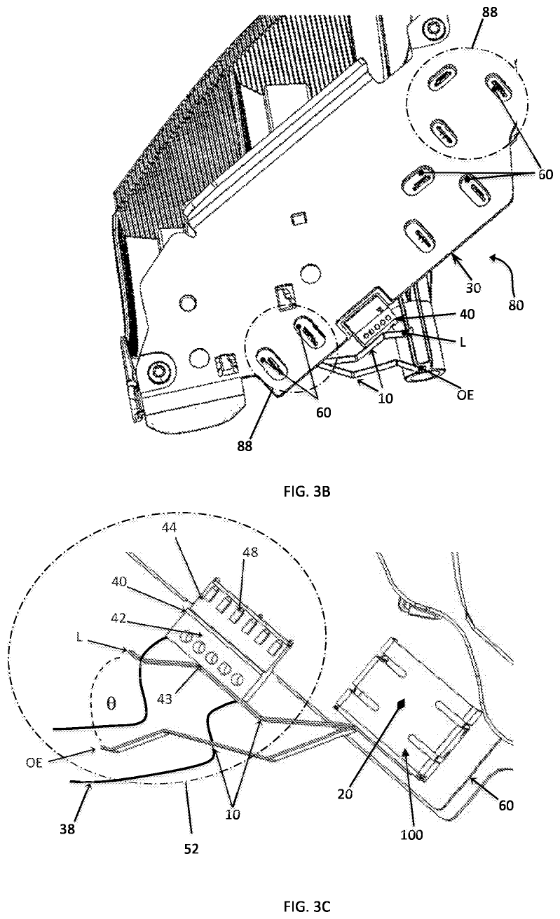

Relief 24 can also facilitate heat transfer and facilitate airflow through the protection site location 88 and shielded electrical elements 94. Flexible leg 10 exhibits biasing or pliant characteristics and extends off from cover body 20 towards engagement or interface 43 with securing onto the connector 40. The characteristics of flexible leg 10 allow flexure and biasing such that flexible leg 10 may be deformed via translation-rotational movement amount θ (as illustrated in FIGS. 1, 3A, 3C) from the free state condition OE or applied locking state condition L.

Movement θ can represent a displacement or angular-radial movement of the flexible leg 10 between the free-state OE, flexed and retention locking condition L. Movement θ may be expressed as a unit measure of deflection in both translational or angular terms and may cover free-state, flexed or applied retention positions that relate to locking states associated with connector interfaces.

In the embodiments of FIGS. 2A and 2B, clip 15 of retention pad 22 is configured to join shield 100 along PCB 60 along a site location 88 in which clip 15 serves as the fastening element. Clip 15 may be formed as an integral part of the body 20 or retention pad 22 can be joined with the component shield 100 by any suitable joining means. Furthermore, it is to be understood that the clip 15 may be joined with the retention pad 22 or joined with both the retention pad 22 and the shield 100. For example, a portion of the retention pad 22 may be an integral part of the shield 100, and another portion such as the clip 15 may be an integral part that interfaces at or along the PCB 60.

This is demonstrably illustrated by the exemplary structure at site location 88 in FIGS. 1 and 3B. As seen, interfaced engagement at a site location 88 may represent retention pad 22 with a retention portion 15 which is part of the body 20 (along retention pad 22) or a retention portion 15 which is part of the PCB 60 (or along a PCB intermediate interface). When the retention pad 22 and PCB 60 are connected, portions of the retention feature (clip 15 by a non-limiting example) form a completed engagement that can be interfaced via an opening through a mounting site at an exemplary site location 88. In such an embodiment, the openings serve as both the receiving element for restricting the retention pads in-place and attaching the retention feature 15 to firmly secure the shield 100 and PCB 60 interface portions and prevent them from disconnecting apart.

Component shield 100 includes a body 20, flexible leg 10 and retention pads 22 that extend downwardly from the body 20. In the embodiment shown, the body 20 includes a retention clip 15 (or similarly suitable retention feature) provided at each end of the retention pad 22. The clip 15 can be made integral or from a separate intermediate portion of any suitable material (such as plastic) for allowing the retention pad 22 and site location 88 interface to deflect or morph under force. In the embodiment shown, the retention clip 15 applies a suitably removable push-in type clip. But any alternative suitable mechanism may be used to engage the associated components in a non-limiting way.

A connector 40 can represent a plug or receptacle that functions as an interface port or an opposing mating component that can serve as a male or female engagement element. With the depicted illustrations, the connector 40 (as seen in FIGS. 3A, 3B, 3C) includes a body 42 with at least one port of PCB site connector 44 having a number of electrical contacts 48 along or within the mating connector portions 46. Flexible leg 10 can secure or engage locking at the connector body 42 at detent 43. The connector 40, site connector 44 and associated body 42 are preferably made of suitable electrical-insulating material such as plastic and the contacts 48 can represent any suitable conductive material such as copper, silver, nickel or any conventional metals. In the embodiment illustrated, the site connector 44 is coupled to the PCB 60 and is designed to interface with a wire harness 38 and locked in place by flexible leg 10.

Flexible leg 10 is configured to flex, bias or bend with sufficiently applied force during installation or removal. Flexible leg 10 is configured to apply a counteractive or retention force against connector 40 to prevent dislodgment, disassembly from adjoining components or cable-wiring 38 and to promote electrical continuity between connector 40 and site connector 44 to avoid failures within the PCB 60 or lighting system 80. A cable-wiring or harness assembly 38 can represent the structure along element 46 that is in communication with connector 40 and that interfaces with site connector 44. The cable-wiring or harness assembly 38 functions to simulate a grouping of electrical or signal pathways to an adjoining assembly system described but not necessarily illustrated in the drawings.

Although the figures illustrate a preferred embodiment of applying removable clips 15, retention pad 22 is not limited to any particular securing means and can represent a removable or permanently fixed hardware method that is enabled by any conventional means or any suitable combination thereof. Lighting module system 80 can represent an automotive product associated with a lighting system or can represent an assembly, sub-assembly or component related to an exterior or interior vehicle lighting system.

FIG. 3A illustrates an embodiment of the invention within lighting system 80 that includes application of component shield 100 with a connector interface at 40 installed along PCB 60 with reflector assembly 90. The site connector 44 is attached to PCB 60, which may be separable or affixed to form part of system 80 or a higher level assembly module. The site connector 44 receives the connector 40 or harness assembly 38. Connector 40 and site connector 44 describe an exemplary form of each respective body 42 with recesses or openings or a pocket which are configured to provide thruway features, ports, electrical contacts 48 or an engagement detent 43 that engage with flexible leg 10 for facilitating retention of mating connector 40 and site connector 44 in a securable connected state and serves to resist disconnection of the connector 40 from an adjoining interface as mentioned herein.

Prior to engagement of the connector 40 with flexible leg 10 of shield 100, the body 42 and flexible leg 10 are separated from each other as shown in FIGS. 1, 3A, 3B and 3C. During assembly, connector 40 and site connector 44 are joined together along an axis (described not illustrated) such that electrical contacts 48 of each respective connector are electrically connected to each other as shown in FIGS. 1 and 3A-3C. The connector 40 and site connector 44 are then moved to align with one another and reinforced into place by flexible leg 10 onto the connector 40 with engagement detent 43 so that the fastening engagement joins and retains mated connector 40 and site connector 44 by locking mechanisms as shown in the illustrations.

Each opposing connector body 42 is suitably dimensioned such that, in a fully connected state, the connector 40 fits within a pocket formed by opposing faces of the sidewalls within site connector 44. Preferably, widths and spaces at opposing ends of mating connector portions provide suitable tolerances for interfacing connector insertions as seen in FIGS. 3A and 3C. Engagement Detent 34 to the body 42 spaces are preferably set such that the flexible leg 10 can only fit within the detent 34 feature in a fully connected state where the contacts are electrically connected. This allows the flexible leg 10 engagement along the connector to provide verification that the connector is properly connected. Furthermore, even in the circumstance that adjoining connector 40 and site connector 44 tend to move away from each other or “back out” due to vibration or dislodging, the flexible leg 10 acts as a restricting member to prevent separation of opposing connector bodies to the extent of electrical disconnection or “backing out” of the connector 40. This feature provides a connector locking function of the cable-wiring or harness assembly 38, making it unnecessary to provide a locking mechanism on the connector portion 44 itself.

In the embodiments of FIGS. 3A and 3C, the component shield 100 includes a site connector 44, a connector 40, and a flexible leg 10. In an illustrated embodiment, the site connector 44 serves as a connector holding member along PCB 60 and can be a part of a housing or framework 54 (described but not shown) of a higher level assembly, such as vehicle lighting module 80. Component shield 100 can be a separate part that is fixed to the housing 54(described but not shown), or integrally formed as part of the housing or framework 54(described but not shown). As described and illustrated, the site connector 44 is provided at the end of a wiring harness 38 having cable or wires, and the connector 40 is provided at the end of wiring harness 38. When the connector 40 and site connector 44 are interfaced, the wires through harness assembly 38 make electrical contact with respective wires and electrical contacts 48, as is described and illustrated herein.

In the connected state, the connector 40 and site connector 44 are provided within engagement location 52. Engagement location 52 represents the connector location along an associated assembly where a connector 40 and flexible leg 10 interface at an engagement detent 43 occurs. Engagement against the connector 40 generally occurs through the flexible leg 10 from shield 100, or through extension 50 from the mask structure 30, being engaged along a connector body to reinforce locking mechanisms between the interfacing components.

As seen in FIGS. 3B and 3C, the connector 40 and site connector 44 include interfacing ports and a locking device via flexible leg 10. Site connector 44 includes suitable cavities each of which accommodate electrical contacts 48, which produce electrically continuity through the connector 40 to the conductors of respective wire-cables from harness assembly 38. Locking portions of connector 40 and site connector 44 include a detent 43 which is a capture engagement feature along the connector 40 by flexible leg 10 when site connector 44 interfaces with the connector 40 as discussed further below.

The connector 40 can include an inserted harness 38 and an engagement detent 43. Connector portion 46 can include cavities which accommodate electrical contact tubes that electrically connect to conductors of respective cable-wires from harness 38. As illustrated, the electrical contacts 48 can be suitably aligned such that interfaces are functionally friction fitted to provide electrical contact when the site connector 44 engages the connector 40. As seen by illustrations in FIGS. 3A, 3B and 3C, electrical contact is enabled through the suitable dimensions of the contacts 48 as well as dimensions of the interfacing connector portions. Furthermore, locking device 1 includes the engagement detent 43 for receiving the flexible leg 10 along the connector body when the site connector 44 engages the connector 40. Thus, interfacing connectors 40 and site connector 44 with flexible leg 10 combined with detent 43 provide a locking mechanism on the connector 40 itself.

The site connector 44 and the connector 40 are dimensioned such that, in a fully connected state, the connector 40 fits within site connector 44 formed along PCB 60. In the embodiment shown, dimensions of the respective connector portions are set so that their interfacing impressions at ends of the connector when inserted into the site connector 44 as seen in FIG. 3C. Interface geometry between the connector 40 and site connector 44 are set by such a fool-proof manner that the connector 40 can only be inserted into site connector 44 in a properly connected state. Furthermore, even if counterpart connector portions tend to back out of a secured connection, flexible leg 10 acts as a restricting member against connector 40 to prevent separation of the connector portions to the extent of electrical disconnection.

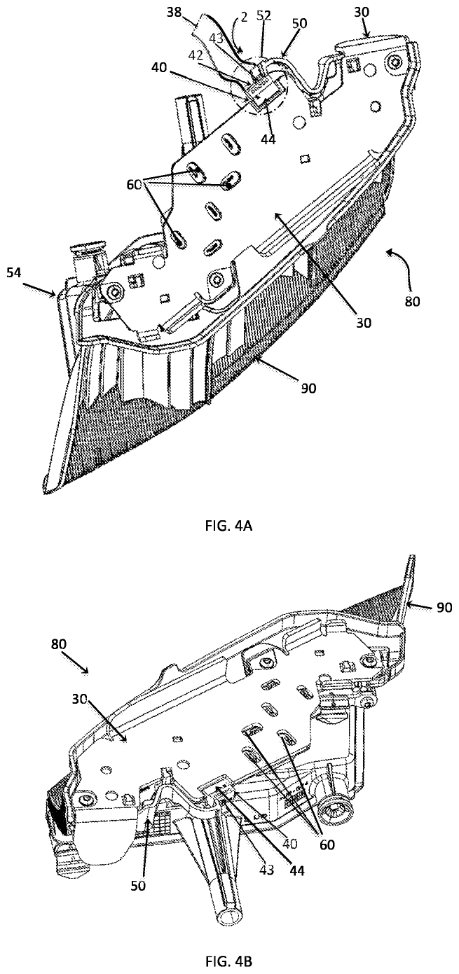

FIGS. 4A and 4B illustrate exemplary lighting module system 80 according to an embodiment of the present invention. The system 80 can represent a headlight, taillight or other lighting device installed on a vehicle. The lighting system 80 includes a light inhibiting structure or a light-blocking member 30 with flexible extension 50 in accordance with any of the embodiments disclosed herein. Masking structure or light-block member 30 functions as a rigid body that can mask light transmission through the body medium and can serve as a mount or intermediate structure for adjoining components within an assembly-subassembly of the associated lighting system 80. Connector locking device 2 is intended to supplement any existing primary locking mechanism associated with connector 40, but nothing should be construed to prevent an interpretation that connector locking device 2 can be used independently apart from any locking features derived from the connectors themselves if necessary or desirable, accordingly.

FIGS. 4A and 4B illustrate feature details of flexible extension 50 from light blocker 30. Flexible extension 50 extends from light block mask structure 30 and applies the inherent material characteristics of the base material that forms light-block structure 30 to provide the biasing or counteracting forces that create the securing retention against connector 40. Retention of securing connector 40 in-place can be implemented through an engagement detent 43 along the connector 40 as shown in FIGS. 4A, 4B.

Flexible extension 50 can be formed from a resilient biasing material, preferably polymeric manufactured from any conventional methods or may be formed from metals or alternatively composite forms. Flexible extension 50 can be formed as a portion from light block structure 30—either by an integrated segment off from a main body or as a segregated part that complements the main body. Flexible extension 50 exhibits biasing or pliant characteristics and extends off light block structure 30 towards an engagement detent 43 or by direct-indirect interface with securing onto connector 40.

The characteristics of flexible extension 50 allows flexure and biasing such that flexible extension 50 may be deformed via translation-rotation movement from the free or retention states. Flexible extension 50 is configured to flex, bias or bend with sufficiently applied force during installation or removal. Flexible extension 50 is designed to articulate between retention-lock and free-state condition modes similar and analagous to the depiction in FIG. 3C where flexible extension 50 would be derived off from mask structure 30 rather than as flexible leg 10 off from shield 100. Illustrations show FIGS. 4A and 4B to represent the locking device 2 where flexible extension 50 is configured to apply a counteractive or retention force against connector 40 to prevent dislodgment or disassembly from adjoining components or detachment away from cable-wiring 38 or an electrical harness 46 to promote electrical continuity between connector 40 and site connector 44 to avoid failures within an assembled PCB 60 or lighting system 80.

Flexible extension 50 can function to hinder or prevent connector 40 from detachment along a PCB 60 or system 80 surface from abrasion, impact or vibrational exposure. The connector locking device 2 can typically be emplaced at an engagement location 52 along interfaces of a PCB 60 or system assembly 80 that are secured in place by suitable means on the associated assembly. In the connected state, the connector 40 and site connector 44 are provided within engagement location 52. Engagement location 52 represents the connector location along an associated assembly where a connector 40 and flexible extension 50 interface at the engagement detent 43. Although the figures illustrate a preferred embodiment of applying flexible extension 50 directly off from structure 30, flexible extension 50 is not limited to directly being from an edge structure of 30 and can represent an intermediate pathway or from a distinguished section off from structure 30.

FIGS. 4A and 4B illustrate embodiments of the invention within lighting system 80 that includes application of flexible extension 50 with the connector 40 and site connector 44 installed along PCB 60 with reflector assembly 90. The site connector 44 is attached to PCB 60, which may be separable or affixed to form part of system 80 or a higher level assembly module. The site connector 44 receives a mating connector 40 or harness assembly 38. Connector 40 and site connector 44 define the form of a respective connector body 42 with recesses or openings or an impression which is configured to provide thruway features, ports, electrical contacts 48 with an engagement detent 43 that engages with flexible extension 50 for facilitating retention of mating connector 40 and site connector 44 in a secured condition and serves to resist against disconnection of connector 40 from its interface as mentioned herein.

Prior to engagement of the connector 40 with flexible extension 50 of mask structure 30 while mating with site connector 44 with flexible extension 50, connector 40 with body 42 and flexible extension 50 are separable from one another analogous to depiction FIG. 3C. During assembly, connector 40 and site connector 44 are joined together along an axis (not illustrated) such that electrical contacts 48 of each respective connector are electrically connected to one another, as depicted in FIGS. 3C, 4A, 4B. The connector bodies 42 are then moved to align with one another and reinforced into place by flexible extension 50 onto connector 40 with engagement detent 43 so that the fastening engagement joins and retains opposing connector 40 and site connector 44 by locking flexible extension 50 as shown in the illustrations.

The lighting system 80 can include electrical elements 48 or a circuit pathway to an electrical element or driver-processor 94 configured to perform lighting functions for a vehicle such as lighting activation-deactivation, activating blinkers, turning lights, signaling, beam intensity variation or flashing by way of non-limiting examples etc. Lighting system 80 can represent any other electrical lighting or electronic device that requires a connector.

It is understood that spatial orientation and references are necessary to properly describe the positions of objects and features relative to another. As such, inherently an orientation axis exists and functions as a reference frame of a depicted illustration relative to an absolute-fixed or relative reference frame of other associated components. An orientation axis can incorporate other axes (e.g. rectilinear, orthogonal, angular, Euclidian reference frames) and can adopt any number of associated rotational, translational, longitudinal, transverse, waterline, vertical, horizontal or vector reference frames as needed to describe orientation, displacement position, translational, angular, sweep or other kinematic movements by the appropriate unit measures.

It is also understood that the related inventive structures generally involve housing containment and framework structure of associated systems, assemblies and components. As such, this application may describe housing-framework 54 (described but not shown) that functions as an outer structure and which can contain a portion or all elements associated with exemplary lighting system 80.

While certain embodiments have been described, these embodiments have been presented by way of example only, and are not intended to limit the scope of the present disclosures. Indeed, the novel apparatuses and systems described herein can be embodied in a variety of other forms; furthermore, various omissions, substitutions and changes in the form of the apparatuses and systems described herein can be made without departing from the spirit of the present disclosures. The accompanying claims and their equivalents are intended to cover such forms or modifications as would fall within the scope and spirit of the present disclosures.

It should be appreciated that the above referenced aspects and examples are non-limiting, as others exist within the present invention as shown and described herein. Unless stated otherwise, dimensions and geometries of the various structures depicted herein are not intended to be restrictive of the invention, and other dimensions or geometries are possible. Plural structural components can be provided by a single integrated structure. Alternatively, a single integrated structure might be divided into separate plural components. In addition, while a feature of the present invention may have been described in the context of only one of the illustrated embodiments, such feature may be combined with one or more other features of other embodiments, for any given application. It will also be appreciated from the above that the fabrication of the unique structures herein and the operation thereof also constitute methods in accordance with the present invention.

### LIST OF ELEMENT NUMBERS

Connector Locking Device 1, 2
Component Shield 100
Flexible Leg 10
Shield Body 20
Retention Feature Clip 15
Retention Pad 22
Relief Cutout Area 24
Heat Shield 33
Cable-Wiring Assembly 38
Connector 40
Connector Body 42
Site Connector 44
Electrical Harness 46
Engagement Detent 43
Electrical Contact 48
Light-Blocking Mask Structure 30
Flexible Extension 50
Flexure Movement θ
Engagement Location 52
Site Location 88
Retention Condition L
Free-state Condition OE
Interface Location IL
Electrical element or Driver-Processor 94
Housing-Framework Structure 54
LED Light Source 70
Lighting Module System 80
Printed Circuit Board (PCB) 60
Reflector Unit Assembly 90

What is claimed is:

1. A connector locking device comprises:
a component shield having a biasing extension along an outer surface of a connector body of the component shield, the component shield configured to interface along an electrical circuit board;
the body of component shield being resilient with a flexible leg that is a biasing extension;
the shield body having a number of retention features along a number of edges of the shield body;
an engagement detent formed along or within a connector body, the flexible leg configured to engage the connector body such that engagement with the connector body provides an associated connector in a connected state in which the first and second electrical contacts are electrically connected to each other; the biasing extension configured to secure the connector to maintain continuous electrical engagement and conductivity with adjoining electrical interfaces within an assembly which includes the connector; and
a port configured to attach the connector to a harness only when the connector is in the connected state.

2. The device of claim 1, wherein the component shield is configured to function as a conductive or thermal heatsink.

3. The device of claim 1, wherein said assembly is incorporated into an automobile product.

4. The device of claim 1, wherein the flexible leg is replaced by a flexible extension that extends from a light-blocking structure or polymeric framework.

5. The device of claim 1, wherein the component shield or flexible leg are formed from a metallic or alloy material.

6. The device of claim 1, wherein the connector body or flexible leg are formed from a polymeric material.

7. The connector locking device of claim 1, where the component shield is applied to a printed circuit board (PCB) with a light source and a reflector unit for reflecting light generated from the light source within the lighting system.

8. The device of claim 1, wherein the component shield interfaces with the connector through the flexible leg and with the connector body on the PCB through a number of retention pads, which are all contained within an automotive lighting system.

9. The device of claim 1, wherein the component shield interfaces with the connector through the flexible leg and with the connector body that is installed at an engagement location, the component shield at the engagement location secured along the PCB through a number of retention pads, which are all contained within an automotive lighting system;
an engagement detent formed along or within the connector body, the flexible leg configured to engage the connector body to prevent extrication or ejection of the connector or prevent the connector from being disengaged or dislodged from a connector port such that a number of electrical contacts of the connector do not break or separate with the connector port while the flexible leg is engaged with the engagement detent.

10. A connector locking device comprises:
an electrical connector installed within a circuit board with a connector body having a number of electrical contacts;
an engagement detent formed along or within the connector body;
a flexible extension with spring properties extending from a masking structure, the masking structure being a rigid structure;
the flexible extension configured to couple with the connector body and configured to place the connector in a locked engagement with a number of adjoining electrical interfaces to maintain continuous electrical engagement or continuity with the adjoining electrical interfaces;
the flexible extension also configured to prevent the extrication or ejection of the connector body from a connector port at an engagement location from the circuit board during operation.

11. The connector locking device of claim 10, wherein the masking structure is formed from a polymeric material.

12. The connector locking device of claim 11, wherein the masking structure possesses light blocking properties.

13. The connector locking device of claim 10, wherein the component shield is located at a site location along the PCB, said component shield configured to protect an electrical element encompassed by a shield body.

14. A connector locking device comprises:
a flexible extension from a light-blocking structure or polymeric framework, the flexible extension configured to exhibit biasing or spring-like characteristics between flexed [L] and un-flexed states [OE], the flexible extension configured to interface at a connector along an electrical printed circuit board (PCB);
the flexible leg having a number of retention features at the connector interface locations with said circuit board;
an engagement detent formed along or within a connector body, the flexible extension configured to engage the connector body to prevent extrication or ejection of the connector body or prevent the connector from being disengaged or dislodged from a PCB port such that a number of electrical contacts of the connector do not break or separate from the PCB port such that the electrical contacts are configured to maintain continuous electrical engagement and conductivity when the connector is in a connected state.
